(19) United States
(12) Patent Application Publication
(10) Pub. No.: US 2009/0010724 A1
(43) Pub. Date: Jan. 8, 2009

(54) COATED CEMENTED CARBIDE INSERTS

(75) Inventors: Susanne NORGREN, Huddinge (SE); Kenneth Westergren, Hagersten (SE)

Correspondence Address: DRINKER BIDDLE & REATH (DC), 1500 K STREET, N.W., SUITE 1100, WASHINGTON, DC, 20005-1209, US

(73) Assignee: SANDVIK INTELLECTUAL PROPERTY AB, Sandviken (SE)

(21) Appl. No.: 12/147,587

(22) Filed: Jun. 27, 2008

(30) Foreign Application Priority Data
Jun. 27, 2007 (SE) 0701548-0

(51) Int. Cl. B23P 15/28; C23C 16/34

(52) U.S. Cl. 407/119; 427/580

(57) ABSTRACT

The present invention relates to cutting insert for dry milling of hard cast steel with a hardness of from about 50 to about 65 HRC comprising a substrate and a coating. The substrate has a hardness of from about 1900 to about 2100 HV3, with a negative chamfer and an edge rounding of 0 (sharp) to about 40 μm. The coating comprises a homogeneous AlₓTi₁₋ₓN-layer with x equals from about 0.6 to about 0.67 and a thickness of from about 1 to about 3.8 μm. The invention also relates to a method of making as well as the use of the inserts.

### CROSS-REFERENCE TO PRIOR APPLICATION

This application claims priority to Sweden Patent Application No. 0701548-0 filed Jun. 27, 2007, which is incorporated by reference herein.

### BACKGROUND OF THE INVENTION

The present invention relates to a coated cutting tool insert particularly useful for milling of hard cast steel. A thin PVD-layer in combination with a special edge geometry giving a sharp edge greatly improves the edge line security, wear resistance in addition to good resistance against plastic deformation.

Milling of hard cast irons and hardened steels can generally be divided in roughing, semi-roughing, semi-finishing and finishing. In milling hardened steel, hard steels, tool steels and cast irons, edge line chipping, plastic deformation and notch wear are the dominant wear mechanisms.

### OBJECTS AND SUMMARY OF THE INVENTION

It is an object of the present invention to provide a cutting tool insert particularly useful for milling hard cast steel.

It is a further object of the present invention to provide a cutting tool insert with improved edge line security, wear resistance in combination with good plastic deformation resistance.

In one aspect of the invention, there is provided a cutting insert comprising a substrate and a coating wherein the substrate has a from about 8 to about 20° negative chamfer with a width of from about 0.1 to about 0.3 mm and an edge rounding of 0 (sharp) to about 40 μm, and a composition of from about 5.4 to about 6.3 wt-% Co, from about 0.4 to about 0.8 wt-% Cr, from about 0.01 to about 0.05 wt-% Ti+Ta with a weight ratio Ti/Ta of from about 1.0 to about 1.7, and balance WC with as sintered Hc-value of 27-35 kA/m, CW_Cr of from about 0.75 to about 0.95 and a hardness of about 1900 HV3 about 2100 HV3, and said coating comprises a homogeneous AlₓTi₁₋ₓN-layer where x equals from about 0.6 to about 0.67 and a thickness of more than about 1 μm but less than about 3.8 μm.

In another aspect of the invention, there is provided a method of making a coated cutting tool insert of a cemented carbide substrate and a coating comprising providing a substrate using conventional powder metallurgical techniques milling, pressing and sintering with a from about 8 to about 20° negative chamfer with a width of from about 0.1 to about 0.3 mm and an edge rounding of 0 (sharp) to about 40 μm with a composition of from about 5.4 to about 6.3 wt-% Co, from about 0.4 to about 0.8 wt-% Cr, from about 0.01 to about 0.05 wt-% Ti+Ta added as TaC and TiC or mixtures of these with a weight ratio Ti/Ta of from about 1.0 to about 1.7 and balance WC with as sintered Hc-value of from about 27 to about 35 kA/m, CW_Cr of from about 0.75 to about 0.95 and a hardness of from about 1900 to about 2100 HV3, and depositing a coating comprising a homogeneous AlₓTi₁₋ₓN-layer where x equals from about 0.6 to about 0.67 and a thickness of more than about 1 μm but less than about 3.8 μm by cathodic arc evaporation using a target material of a TiAl-alloy of suitable composition in an N₂ gas atmosphere.

In still a further aspect of the invention, there is provided the use of the insert described above for dry milling in hard cast steel with hardness from about 50 to about 65 HRC at a cutting speed of from about 50 to about 180 m/min and a feed of from about 0.1 to about 0.4 mm/rev.

### BRIEF DESCRIPTION OF THE DRAWINGS

FIG. 1 shows a cross-section of the edge of an insert. Two lines (L1 and L2) being respectively parallel and normal to the support face id drawn. From these two lines, two reference points RP1 and RP2) are found, from which we further find the center (C). The edge rounding (ER) is defined as the average distance at five different angles (R1 to R5) from the center of the edge. Also the flank side (FS) and chamfer (CH) are shown in the figure.

FIG. 2 shows a cross-section of the edge of an insert according to the present invention.

CH=Chamfer

RS=Rake Side

FS=Flank Side

CW=Chamfer Width

CA=Chamfer Angle

ER=Edge Rounding

### DETAILED DESCRIPTION OF THE PREFERRED EMBODIMENTS

It has now surprisingly been found that a hard cubic carbide containing cemented carbide substrate combined with a relatively thin PVD-layer in combination with a special edge geometry giving a sharp edge greatly improves the edge line security, wear resistance in addition to good resistance against plastic deformation resulting in increased tool life and surface quality on the workpiece surfaces when dry milling in hardened steels and hard cast irons with hardness from about 50 to about 65 HRC.

The substrate comprises a cemented carbide with a hardness of from about 1900 HV3 to about 2100 HV3 preferably with the composition from about 5.4 to about 6.3, preferably from about 5.7 to about 6.1, wt-% Co, from about 0.4 to about 0.8, preferably from about 0.45 to about 0.75, and most preferably from about 0.5 to about 0.7, wt-% Cr, from about 0.01 to about 0.05, preferably from about 0.015 to about 0.04, and most preferably from about 0.02 to about 0.035, wt-% Ti+Ta with a weight ratio Ti/Ta of from about 1.0 to about 1.7, preferably from about 1.2 to about 1.5, and balance WC with as sintered Hc-value of from about 27 to about 35, preferably from about 29 to about 34, kA/m.

The cobalt binder phase is alloyed with of W giving the invented cemented carbide cutting insert its desired properties. W in the binder phase influences the magnetic properties of cobalt and can hence be related to a value, CW_Cr ratio, defined as

CW_Cr=(magnetic-% Co+1.13*wt-% Cr)/wt-% Co

where magnetic-% Co is the weight percentage of magnetic Co, wt-% Cr is the weight percentage of Cr and wt-% Co is the weight percentage of Co in the cemented carbide. The CW_Cr ratio is a function of the W content in the Co binder phase. A CW_Cr of about 1 corresponds to a very low W-content in the binder phase and a CW_Cr of from about 0.75 to about 0.8 corresponds to a high W-content in the binder phase. For the cemented carbide according to the invention, CW_Cr is from about 0.75 to about 0.95, preferably from about 0.78 to about 0.90.

The sintered body may also contain small amounts of precipitations of additional phase or phases such as eta-phase, MX or M₇X₃, M₃X₂ where M=(Ti+Ta+Co+Cr+W) and X=C or N maybe allowed to a volume fraction of maximum about 0.5 vol % without detrimental effects.

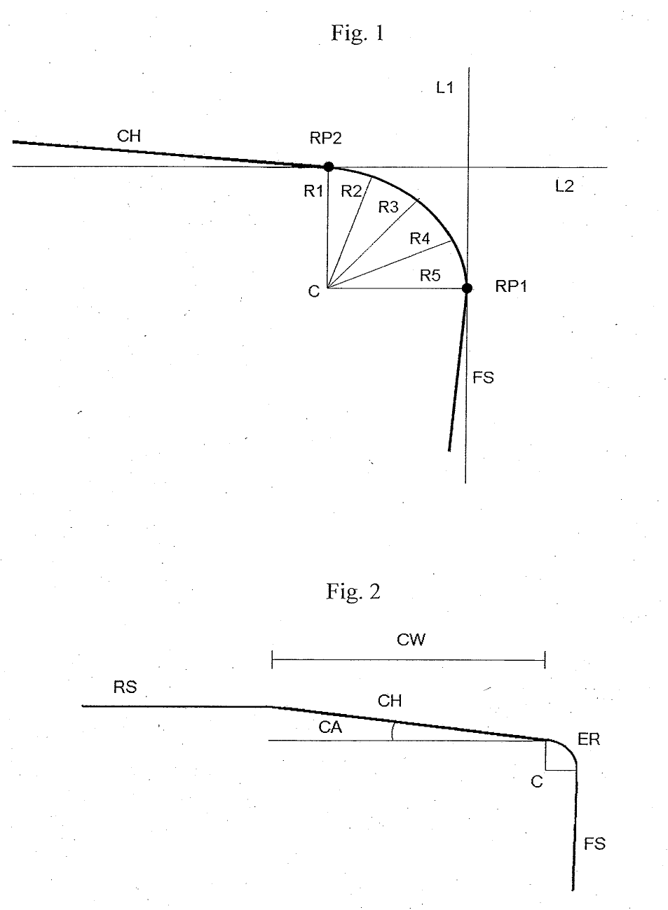

The uncoated substrates have a from about 8 to about 20°, preferably from about 9 to about 15°, negative chamfer with a width of from about 0.1 to about 0.3, preferably from about 0.15 to about 0.25, mm and an edge rounding of 0 (sharp) to about 40 μm. The procedure of measuring the edge rounding is illustrated in FIG. 1.

FIG. 1 is an illustration of how to measure the edge rounding (ER) of a cutting edge. The edge of an insert usually displays an arc shape called the edge rounding. ER can be measured from a polished cross-section of an insert, being cut normal to the cutting edge. The ER is defined by drawing a line parallel to the inserts support face, and another line normal to the first. The two points, where the shape of the insert tangents or deviates from these straight lines, are called reference points (RP1 and RP2). From the two reference points, another two lines are drawn, parallel to the first two lines. The intersection of the two lines going through the reference points, are called the center (C). Measuring the distance from the center to the edge at 0, 22.5, 45, 67.5 and 90 degrees (R1, R2 . . . R5) and calculating the average, gives the ER.

The coating comprises a homogeneous AlₓTi₁₋ₓN-layer where x equals from about 0.6 to about 0.67, preferably x equals about 0.62. The total thickness of the layer is more than about 1 μm, preferably more than about 1.8 μm, but less than about 3.8 μm, preferably less than about 3.0 μm. Both the composition and the thickness are determined on the flank face about 1 mm from the nose radius and about 200 μm from the cutting edge.

The present invention also relates to a method of making a coated cutting tool insert consisting of a cemented carbide substrate and a coating using conventional powder metallurgical techniques, milling, pressing and sintering, and deposition technique.

The substrate comprises a cemented carbide with the composition from about 5.4 to about 6.3, preferably from about 5.7 to about 6.1 wt-% Co, from about 0.4 to about 0.8, preferably from about 0.45 to about 0.75 and most preferably from about 0.5 to about 0.7, wt-% Cr, from about 0.01 to about 0.05, preferably from about 0.015 to about 0.04 and most preferably from about 0.02 to about 0.035, wt-% Ti+Ta added as TaC and TiC or mixtures of these with a weight ratio Ti/Ta of from about 1.0 to about 1.7, preferably from about 1.2 to about 1.5, and balance WC.

The substrates are compacted to have a from about 8 to about 20°, preferably from about 9 to about 15°, negative chamfer with a width of from about 0.1 to about 0.3, preferably from about 0.15 to about 0.25 mm and an edge rounding of 0(sharp) to about 40 μm.

The cemented carbide is sintered to obtain an Hc-value of from about 27 to about 35, preferably from about 29 to about 34, kA/m, with a hardness of from about 1900 to about 2100 HV3, preferably, and a CW_Cr of from about 0.75 to about 0.95, preferably from about 0.78 to about 0.90.

After conventional post sintering treatment, a coating comprising AlₓTi₁₋ₓN where x equals from about 0.6 to about 0.67, preferably x equals about 0.62, is deposited by cathodic arc evaporation using a target material of a TiAl-alloy of suitable composition, in an N₂ gas atmosphere. The total thickness of the layer is more than about 1 μm, preferably more than about 1.8 μm, but less than about 3.8 μm, preferably less than about 3.0 μm.

The present invention also relates to the use of the insert according to above for dry milling in hard cast steel with hardness from about 50 to about 65 HRC at a cutting speed of from about 50 to about 180 m/min and a feed of from about 0.1 to about 0.4 mm/rev.

The invention is additionally illustrated in connection with the following examples, which are to be considered as illustrative of the present invention. It should be understood, however, that the invention is not limited to the specific details of the examples.

### Example 1

A. (Invention) Cemented carbide milling inserts, SECT120612 T02010, in accordance with the invention with a negative chamfer of 10° and a chamfer width of 0.2 mm and an edge rounding of 20 μm and the composition 6 wt-% Co, 0.6 wt-% Cr, 0.026 wt-% Ta+Ti added as TaC and TiC with the weight ratio Ti/Ta=11.4 and balance WC with an as sintered Hc-value of 30.1 kA/m and a hardness of 1960 HV3 with a binder phase alloyed with W corresponding to a CW-CR ratio of 0.86 were coated with a 2.9 μm homogeneous Al_{0.62}Ti_{0.38}N—PVD-layer by cathodic arc evaporation using a target material of a Ti₃₃Al₆₇-alloy. The arc evaporation was performed in an N₂ gas atmosphere.

B. (prior art) Cemented carbide milling inserts, SECT120612 T02010 with a negative chamfer of 10° and a chamfer width of 0.2 mm and the composition 5.90 wt-% Co, 0.56 wt-% Ta, 0.35 wt-% Nb, 6.16 wt-% Ti added as TaC, NbC and TiC and balance WC with as sintered Hc-value of 23 kA/m and a hardness of 1825 HV3 and with a binder phase alloyed with W corresponding to a CW_Cr-ratio of 0.86 were coated as in A.

C. (Reference) Commercial cemented carbide milling inserts, SECT120612 T02010, with a negative chamfer of 10° and a chamfer width of 0.2 mm and the composition of 3.70 wt-% Co, 1.43 wt-% Ta, 0.42 wt-% Nb and balance WC and with an Hc-value of 23 kA/m and a CW_Cr-ratio of 0.9 and a hardness of 1830 HV3 were coated with a 2.9 μm (Ti,Al)N PVD-layer as in A.

### Example 2

Inserts from A and B were tested in milling of a hard cast steel.

Operation: Side long edge milling

Work-piece: Stator and rotator segment

Material: Austenitic steel with carbides, C=1.15
Hardness 55 HRC

Milling Cutter: diameter 80 mm

Total number of teeth: 35 (with z=5 and 7 rows)

Cutting speed: 140 m/min (n=557)

Feed rate: 780 mm/min (fz=0.28)

Depth of cut: Radial Aₑ=1.5 mm axial Aₚ=50-72 mm

Insert-style: SECT120612 T02010

Note: Dry milling

Criteria for replacing inserts: edge line chipping and/or risk of insert breakage.

Results:

Grade A: (invention) 32 segments

Grade B: (prior art) 14 segments

Grade C: (reference) 8 segments

### Example 3

Inserts from A, B and C were tested in milling of a hard cast steel.

Operation: Side long edge milling

Work-piece: Stator and rotator segment

Material: Austenitic tool steel
Hardness 62 HRC

Milling Cutter Diameter 80 mm

Total number of teeth: 35 (with z=5 and 7 rows)

Cutting speed: 90 m/min (n=358)

Feed rate: 340 mm/min (fz=0.19)

Depth of cut: radial Ae=1.5 mm axial Ap=50-72 mm

Insert-style: SECT120612 T02010

Note: Dry milling

Criteria for replacing inserts: edge line chipping and/or risk of insert breakage.

Results:

Grade A: (invention) 18 segments

Grade B: (prior art) 12 segments

Grade C: (reference) 3 segments

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

1. Cutting insert comprising a substrate and a coating wherein
the substrate has a from about 8 to about 20° negative chamfer with a width of from about 0.1 to about 0.3 mm and an edge rounding of 0(sharp) to about 40 μm and a composition of from about 5.4 to about 6.3 wt-% Co, from about 0.4 to about 0.8 wt-% Cr, from about 0.01 to about 0.05 wt-% Ti+Ta with a weight ratio Ti/Ta of from about 1.0 to about 1.7, and balance WC with as sintered Hc-value of 27-35 kA/m, CW_Cr of from about 0.75 to about 0.95 and a hardness of from about 1900 HV3 to about 2100 HV3 and
said coating comprises a homogeneous AlₓTi₁₋ₓN-layer where x equals from about 0.6 to about 0.67 and a thickness of more than about 1 μm but less than about 3.8 μm.

2. Cutting insert of claim 1 wherein the substrate has a from about 9 to about 15° negative chamfer with a width of from about 0.15 to about 0.25 mm and
a composition of from about 5.7 to about 6.1 wt-% Co, from about 0.45 to about 0.75 wt-% Cr, from about 0.015 to about 0.04 wt-% Ti+Ta with a weight ratio Ti/Ta of from about 1.2 to about 1.5, and balance WC with as sintered Hc-value of from about 29 to about 34 kA/m and CW_Cr of from about 0.78 to about 0.90.

3. Cutting insert of claim 1 wherein the substrate comprises from about 0.5 to about 0.7 wt-% Cr and from about 0.02 to about 0.035 wt-% Ti+Ta.

4. Cutting insert of claim 1 wherein the AlₓTi₁₋ₓN-layer has a thickness of more than about 1.8 μm but less than about 3.0 μm.

5. Cutting insert of claim 1 wherein the AlₓTi₁₋ₓN-layer has a composition where x equals about 0.62.

6. Method of making a coated cutting tool insert of a cemented carbide substrate and a coating comprising providing a substrate using conventional powder metallurgical techniques milling, pressing and sintering with a from about 8 to about 20° negative chamfer with a width of from about 0.1 to about 0.3 mm and an edge rounding of 0(sharp) to about 40 μm with a composition of from about 5.4 to about 6.3 wt-% Co, from about 0.4 to about 0.8 wt-% Cr, from about 0.01 to about 0.05 wt-% Ti+Ta added as TaC and TiC or mixtures of these with a weight ratio Ti/Ta of from about 1.0 to about 1.7 and balance WC with as sintered Hc-value of from about 27 to about 35 kA/m, CW_Cr of from about 0.75 to about 0.95 and a hardness of from about 1900 to about 2100 HV3 and
depositing a coating comprising a homogeneous AlₓTi₁₋ₓN-layer where x equals from about 0.6 to about 0.67 and a thickness of more than about 1 μm but less than about 3.8 μm by cathodic arc evaporation using a target material of a TiAl-alloy of suitable composition, in an N₂ gas atmosphere.

7. Method of claim 6 wherein the substrate has a from about 9 to about 15° negative chamfer with a width of from about 0.15 to about 0.25 mm with a composition of from about 5.7 to about 6.1 wt-% Co, from about 0.45 to about 0.75 wt-% Cr, from about 0.015 to about 0.04 wt-% Ti+Ta added as TaC and TiC or mixtures of these, with a weight ratio Ti/Ta of from about 1.2 to about 1.5, and balance WC with as sintered Hc-value of from about 29 to about 34 kA/m, and CW_Cr of from about 0.78 to about 0.90.

8. Method of claim 6 wherein the substrate comprises from about 0.5 to about 0.7 wt-% Cr and from about 0.02 to about 0.035 wt-% Ti+Ta.

9. Method of claim 6 wherein the AlₓTi₁₋ₓN-layer has a thickness of more than about 1.8 μm but less than about 3.0 μm.

10. Method of claim 6 wherein the AlₓTi₁₋ₓN-layer has a composition where x equals about 0.62

11. Use of the insert according to claim 1 for dry milling in hard cast steel with hardness from about 50 to about 65 HRC at a cutting speed of from about 50 to about 180 m/min and a feed of from about 0.1 to about 0.4 mm/rev.
